(19) United States
(12) Patent Application Publication
(10) Pub. No.: US 2010/0068011 A1
(43) Pub. Date: Mar. 18, 2010

(54) PALLET CONVEYANCE DEVICE AND SUBSTRATE INSPECTION DEVICE

(75) Inventor: Gaku Tanaka, Kyoto-shi (JP)

Correspondence Address: DARBY & DARBY P.C., P.O. BOX 770, Church Street Station, New York, NY, 10008-0770, US

(73) Assignee: Shimadzu Corporation, Kyoto-Shi (JP)

(21) Appl. No.: 12/516,234

(22) PCT Filed: Dec. 5, 2006
(86) PCT No.: PCT/JP2006/324248

§ 371 Date: May 26, 2009

(51) Int. Cl. B65G 49/06; H01L 21/677

(52) U.S. Cl. 414/222.07; 414/222.01

(57) ABSTRACT

A pallet conveyance device has, besides a mechanism for moving a pallet for supporting a substrate, a lifting mechanism for vertically moving the pallet. The lifting mechanism has an impact cushioning mechanism for cushioning an impact applied to the substrate supported on the pallet. When an impact is applied to the substrate from the pallet, the impact cushioning mechanism controls a vertical motion of the lifting mechanism to cushion the impact applied to the substrate supported on the pallet. The impact cushioning mechanism is a mechanism that changes the drive speed of the lifting mechanism. The impact cushioning mechanism changes the drive speed to a low speed at at least either the start of operation of the lifting mechanism or before the end of the operation, and in a drive period excluding a low speed period, the impact cushioning mechanism changes the drive speed to a high speed.

### CROSS REFERENCE TO RELATED APPLICATION

This is a U.S. national phase application under U.S.C. §371 of International Patent Application No. PCT/JP2006/324248 filed Dec. 5, 2006. The International Application was published on Jun. 12, 2008 as International Publication No. WO/2008/068845 under PCT Article 21(2) the contents of which are incorporated herein in its entirety.

### TECHNICAL FIELD

The present invention relates to a pallet conveyance device that moves pallets that support a substrate, and to substrate inspection device that contain this pallet conveyance device; and this substrate inspection device can be applied to a liquid crystal substrate inspection device for inspecting liquid crystal substrates used in liquid crystal displays, organic EL displays, and the like.

### BACKGROUND OF THE INVENTION

Liquid crystal substrates and thin film transistor array substrates (TFT array substrate) constitute TFT arrays, in which thin film transistors (TFT) are arranged in a matrix shape on a substrate such as glass substrate, and signal electrodes that supply drive signals to these thin film transistors; and the thin film transistors are driven by signals from scanning signal electrode terminals and video signal electrode terminals.

Substrate inspection devices such as TFT array inspection devices and liquid crystal substrate inspection devices are known as devices that inspect TFT arrays formed on substrate and liquid crystal substrates. Substrate inspection devices are composed of probers and an inspection circuit for inspecting the electrical connections of scan signal electrode terminals and video signal electrode terminals. The inspection circuit applies a specified voltage to the inspection probers, detects the flow of current caused by that application of voltage, and investigates for short circuits between the gate and source, point defects, disconnected lines, and the like.

TFT arrays formed on liquid crystal substrate come in a variety of sizes and specifications, differ in layouts, and have differing drive electrodes formed on the liquid crystal substrate depending on the layout. For those reasons, substrate inspection devices used to inspect liquid crystal substrate set up the electrode positions of the inspection prober electrodes corresponding to the TFT array layout, and inspections are conducted by substituting these positions corresponding to the liquid crystal substrate to be inspected.

When inspecting liquid crystal substrates, a prober frame is stacked from above or below the liquid crystal substrate, the probe pins provided on the prober frame make contact with the electrodes of the liquid crystal substrate, and this contact between the probe pins and the electrodes makes electrical contact between the liquid crystal substrate and the prober.

Inspection of semiconductor substrates, which is not limited to the liquid crystal substrate described above, is conducted in an inspection chamber. To inspect substrate in this inspection chamber, the substrate is mounted on a pallet, this pallet is conveyed from a load lock chamber into the inspection chamber, and the inspected substrate is discharged together with the pallet.

Pallets can be conveyed between the inspection chamber and the load lock chamber by conveyance rollers provided respectively in the inspection chamber and the load lock chamber. By providing conveyance rollers in these chambers, the pallets can be moved in the chambers, and the pallets can be transferred between the inspection chamber and the load lock chamber.

In order to heighten the efficiency of substrate conveyance in the inspection process, a configuration can be adopted in which several pallets are arranged up and down in the load lock chamber, and pallets are switched with the conveyance rollers by moving the pallets up and down.

When moving the pallets up and down to switch the pallets with conveyance rollers, the pallets accelerate when changing from a static state to a drive state, or when changing from a drive state to a static state. Meanwhile, when a substrate is mounted on a pallet, the substrate is no more than simply placed on the pallet, and therefore, when the pallet is moving, the inertia of the substrate generates a discrepancy between the movement of the pallet and the movement of the substrate, and the substrate is subjected to impact.

In this kind of configuration, when heightening the velocity of the up and down movement of the pallet in order to quicken the substrate conveyance process and to improve the processing approach of the substrates, acceleration of pallets becomes greater. Therefore, the substrates are subjected to a greater impact and there is the risk of substrates being damaged by this impact.

Thus, to address the aforementioned problems of the past, an object of the present invention is to reduce damage to substrates caused by impact generated by pallet drive when conveying substrates using pallets in pallet conveyance devices and in substrate inspection devices containing pallet conveyance devices.

### SUMMARY OF THE INVENTION

In addition to a mechanism to move the pallets that support the substrate, the pallet conveyance device of the present invention is also equipped with a lifting mechanism to move the pallets up and down. This lifting mechanism is equipped with an impact cushioning mechanism that cushions the impact to which the substrate that is supported on the pallet is subjected during the lifting operation.

As previously described, when moving a pallet up and down using a lifting device, the inertia of the substrate generates a discrepancy between the movement of the pallet and the movement of the substrate, and may thereby be subjected to impact.

For example, if a pallet on which a substrate is mounted is lifted by a lifting mechanism, the velocity of the pallet is decelerated when stopping the lifting operation, but the velocity of the substrate mounted on the pallet is maintained by inertia at that time. For that reason, the substrate moves in a direction to separate from the pallet, and afterwards lands on the pallet by the force of gravity. The substrate is impacted by the pallet at this time.

Moreover, when the lifting mechanism lowers a pallet on which a substrate is mounted, the velocity of the pallet is accelerated downward from the stop position, and the substrate mounted on the pallet attempts to remain stationary at that time by the force of inertia. For that reason, the substrate temporarily moves toward separation from the pallet, and afterward lands on the pallet by the force of gravity. At that time, the substrate is impacted by the pallet.

In operations when the pallet impacts the substrate as described above, the impact cushioning mechanism of the present invention cushions the impact imparted to the substrate supported on the pallet by controlling the lifting operation of the lifting mechanism.

The impact cushioning mechanism of the present invention is a mechanism that switches the drive velocity of the lifting mechanism, switches the drive velocity of the pallet to low speed after beginning operation and before ending operation of the lifting mechanism, and switches the drive velocity of the pallet to high speed in drive periods other than the low speed periods. Here, the periods of switching the pallet drive velocity to low speed are the periods when the velocity changes during start up and termination of the drive operation, and are the periods when velocity discrepancies are generated between the pallet and the substrate. In this period the extent of velocity change is reduced and the positional discrepancy between the pallet and substrate is decreased by decelerating the pallet drive velocity, thereby reducing the impact on the substrate.

For example, during the lifting operation of the lifting mechanism, the lifting operation is begun at the high-speed drive velocity and the drive velocity is switched to low-speed prior to completing the lifting operation. By switching and controlling this drive velocity in the lifting operation of the lifting mechanism, the pallet drive velocity is decreased prior to stopping the lifting operation, and the impact imparted to the substrate when stopping the pallet can be reduced by conducting the stop operation from the low-speed state. Further, when beginning the lifting operation, upward facing force acts on the substrate from the pallet, and therefore there is little velocity discrepancy between the substrate and the pallet and no impact is imparted to the substrate by positional discrepancy between the pallet and the substrate.

Meanwhile, during the lowering operation of the lifting mechanism, the lowering operation is begun at the low-speed drive velocity, and then after having passed through a specified period from the beginning of the lowering operation, the drive velocity is switched to high-speed. By switching and controlling this drive velocity in the lowering operation of the lifting mechanism, the impact imparted to the substrate when lowering the pallet can be reduced by decelerating the pallet drive velocity when beginning the lowering operation.

Further, when stopping the lowering operation, upward facing force acts from the pallet to the substrate, and therefore there is little velocity discrepancy between the substrate and the pallet and no impact is imparted to the substrate by positional discrepancy between the pallet and the substrate.

An air cylinder mechanism that is driven by pneumatic pressure is used as one configuration of the lifting mechanism of the present invention. This impact cushioning mechanism has two compressed air line systems, a high-speed compressed air line and a low-speed compressed air line, which supply gas at differing flow rates into the air cylinder mechanism.

In these 2 compressed air line systems the flow rate of gas that the low-speed compressed air line supplies to the air cylinder mechanism is set up to be less than the flow rate of gas that the high-speed compressed air line supplies to the air cylinder mechanism.

When supplying gas to the air cylinder system using the low-speed compressed air line, the supply rate of gas supplied to the air cylinder mechanism per unit time is small, and therefore the drive velocity of the air cylinder mechanism is low-speed, and the movement velocity of the pallet that is driven by this air cylinder is low-speed. Meanwhile, when supplying gas to the air cylinder system using the high-speed compressed air line, the supply rate of gas supplied to the air cylinder mechanism per unit time is large compared to that of the low-speed compressed air line, and therefore the drive velocity of the air cylinder mechanism is high-speed, and the movement velocity of the pallet that is driven by this air cylinder is high-speed.

The lifting mechanism is not limited to the aforementioned air cylinder mechanism, and may be a motor-driven mechanism ancillary to the device. In a motor-driven mechanism, for example, adjusting the drive current can control the pallet movement velocity.

Moreover, the impact to the substrate is cushioned by switching the pallet drive velocity between high speed and low speed; and the pallet conveyance time can be shortened and the substrate conveyance time can be shortened by switching to high-speed drive.

The lifting mechanism of the present invention can be applied to pallet conveyance devices that move multiple pallets supporting substrates. In this aspect, the device is composed of the aforementioned lifting mechanism and of a conveyance mechanism that moves one of the multiple pallets horizontally. The lifting mechanism can individually move the multiple pallets up and down or can move and switch a pallet to and from the conveyance mechanism, and the pallet is moved and switched by moving up and down and to and from the conveyance mechanism.

Further, the pallet conveyance device of the present invention can be applied to a substrate inspection device. In the aspect of a substrate inspection device of the present invention, the substrate inspection device is composed of an inspection chamber for inspecting substrates, and a load lock chamber for conveying substrates to and from the inspection chamber; and the load lock chamber constitutes the pallet conveyance device of the present invention. The conveyance mechanism is composed of a first set of conveyance rollers provided in an inspection chamber for inspecting substrates, and a second set of conveyance rollers provided in the load lock chamber for conveying substrates in and out of the inspection chamber. The multiple pallets that the lifting mechanism supports in the load lock chamber are conveyed to and from the first set of conveyance rollers by sharing the second set of conveyance rollers.

When conveying substrates using pallets, a pallet conveyance device according to the present invention, and a substrate inspection device composed of this pallet conveyance device, can reduce substrate damage caused by impact generated by pallet drive.

### BRIEF DESCRIPTION OF THE DRAWINGS

FIG. 1 is a schematic diagram for explaining a pallet conveyance device of the present invention and a substrate inspection device composed of this pallet conveyance device;

FIG. 2 is a diagram for explaining an example of the configuration of a lifting mechanism of the present invention;

FIG. 3 is a flowchart for explaining the low-speed switching operation when operation of the lifting mechanism of the present invention is stopped;

FIGS. 4(a)-4(d) are operational diagrams for explaining low-speed switching operations while stopping during the lifting operations of the lifting mechanism of the present invention;

FIGS. 5(a)-5(d) are operational diagrams for explaining the low-speed switching operations while starting during lowering the lowering operations of the lifting mechanism of the present invention;

FIGS. 6(a)-6(c) are diagrams for explaining the drive of just the high-speed line;

FIGS. 7(a)-7(e) are perspective diagrams for explaining an example of the operation of the conveyance mechanism and lifting mechanism of the present invention;

FIGS. 8(a)-8(c) are cross-sectional diagrams for explaining an example of the operation of the conveyance mechanism and lifting mechanism of the present invention;

FIGS. 9(a)-9(c) cross-sectional diagrams for explaining an example of the operation of the conveyance mechanism and lifting mechanism of the present invention;

FIG. 10 is a flowchart for explaining an example of the operation of the pallet conveyance device of the present invention;

FIG. 11 is a flowchart for explaining an example of the operation of the pallet conveyance device of the present invention;

FIGS. 12(a)-12(d) are operational charts for explaining an example of the operation of the pallet conveyance device of the present invention;

FIGS. 13(a)-13(d) are operational charts for explaining an example of the operation of the pallet conveyance device of the present invention;

FIGS. 14(a)-14(d) are operational charts for explaining an example of the operation of the pallet conveyance device of the present invention;

FIGS. 15(a)-15(e) are operational charts for explaining an example of the operation of the pallet conveyance device of the present invention;

FIGS. 16(a)-16(d) are operational charts for explaining an example of the operation of the pallet conveyance device of the present invention;

FIGS. 17(a)-17(c) are operational charts for explaining an example of the operation of the pallet conveyance device of the present invention;

FIGS. 18(a)-18(c) are operational charts for explaining an example of the operation of the pallet conveyance device of the present invention;

FIGS. 19(a)-19(c) are operational charts for explaining an example of the operation of the pallet conveyance device of the present invention; and

FIGS. 20(a)-20(c) are operational charts for explaining an example of the operation of the pallet conveyance device of the present invention.

### DETAILED DESCRIPTION OF THE INVENTION

Aspects of implementing the present invention will be explained in detail below while referring to the diagrams.

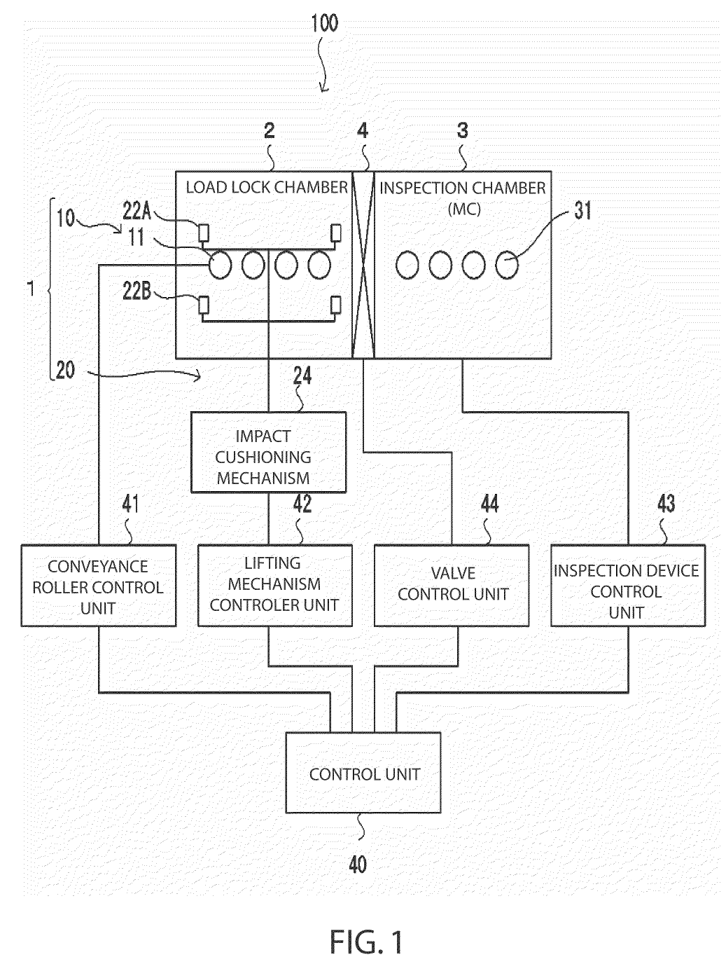

FIG. 1 is a schematic diagram for explaining a pallet conveyance device of the present invention and a substrate inspection device composed of this pallet conveyance device. Further, part of the configuration of the substrate inspection device is also indicated here.

A substrate inspection device 100 is composed of an inspection chamber 3 where the introduced substrate (not indicated in the diagram) is inspected, a load lock chamber 2 from which the substrates are conveyed into and out of the inspection chamber 3, and a gate valve 4 that can freely seal and open between the inspection chamber 3 and the load lock chamber 2.

The inspection chamber (MC) 3 is a chamber for inspecting semiconductor substrate such as liquid crystal substrate, and the substrate, which is mounted on a pallet, is conveyed onto the conveyance rollers 31 inside the inspection chamber though the gate valve 4. The substrate that has been conveyed into inspection chamber 3 is inspected, and after inspection has ended, the substrate, which is mounted on a pallet, is conveyed out through the gate valve 4 by the conveyance rollers 31.

An example of the inspection of a liquid crystal substrate conducted in the inspection chamber will be explained below. Further, the configuration to be explained below is not indicated in FIG. 1.

The liquid crystal substrate inspection device is composed of a charged particle source that irradiates a charged particle beam on the liquid crystal substrate targeted for inspection, a detector that detects secondary electrons emitted from the liquid crystal substrate based on the irradiation of these charged particles, and other parts such as a stage that supports and two-dimensionally scans the liquid crystal substrate targeted for inspection; and substrate inspection is conducted based on scan images obtained by the detector.

The liquid crystal substrate constitutes, for example, a TFT array formed on a glass substrate. The layout, electrodes, routing pattern, and the like of the TFT array formed on this liquid crystal substrate may be set up in a variety of ways corresponding to the size of the liquid crystal panel and the specifications. Thin film transistors formed in a matrix and signal electrode terminals (for example, scan signal electrode terminals, video signal electrode terminals), which drive the thin film transistors, are formed in the TFT array on the liquid crystal substrate. Moreover, an electrode is formed outside of the array on the liquid crystal substrate for electrically connecting with a unit exterior to the liquid crystal substrate.

In addition, the liquid crystal substrate inspection device is composed of a prober (not indicated in the diagram) that supplies inspection signals to the liquid crystal substrate. The prober is composed of a prober frame (not indicated in the diagram) for electrically connecting with the electrodes of the liquid crystal substrate and conducting inspections, and of probe pins (not indicated in the diagram) for electrically connecting with the electrodes of the liquid crystal substrate.

In order to inspect the liquid crystal substrate, the probe frame is arranged on the liquid crystal substrate that is mounted on a pallet. The probe pins coming into contact with the electrodes make an electrical connection between the liquid crystal substrate and the prober frame, and inspection signals are supplied to the TFT array through the connection between the probe pins and the electrodes. Moreover, the connection between the prober framer and the pallet or stage is made by a connector (not indicated in the diagram) provided on the prober frame and the pallet.

Further, the pallet can move freely by being mounted on a stage (not indicated in the diagram). The electrical connection between the pallet and the stage can be made by a pallet-side connector provide on the pallet and a stage-side connector provided on the stage side.

The inspection device and the conveyance rollers 31 provided inside the inspection chamber 3 are controlled by an inspection device control unit 43, which is controlled by a control unit 40.

The load lock chamber 2 is a chamber where substrates are introduced from the outside, substrates mounted on a pallet are conveyed into the inspection chamber 3, inspected substrates mounted on pallets are conveyed out from the inspection chamber 3, and the substrates are returned to the outside; and load lock chamber 2 has a configuration in which multiple pallets can be arranged up and down in order to efficiently convey substrates in and out of the inspection chamber 3.

A pallet conveyance device 1, which moves the multiple pallets horizontally as well as up and down, is provided inside the load lock chamber 2. This pallet conveyance device 1 is composed of a conveyance mechanism 10, which has a set of conveyance rollers 11 that moves pallets horizontally and conveys pallets in and out of the inspection chamber 3, and a lifting mechanism 20 that moves and switches pallets with the conveyance rollers 11 by moving pallets up and down.

The conveyance rollers 11 of the conveyance mechanism 10 constitute a mechanism that moves pallets horizontally in the load lock chamber 2, and conduct operations to introduce and discharge substrates between the load lock chamber 2 and the outside, and operations to convey substrates in and out of the inspection chamber 3. This conveyance mechanism 10 is controlled by a conveyance roller control unit 41 that is controlled by a control unit 40.

The lifting mechanism 20 is provided above and below with multiple pallet support parts 22A, 22B that support pallets, and is driven by an air cylinder mechanism (not indicated in FIG. 1) by pneumatic pressure. The air cylinder mechanism of this lifting mechanism switches lifting velocities using an impact cushioning mechanism 24. Switching lifting velocities using this impact cushioning mechanism 24 is conducted by switching the flow rate of gas supplied to the air cylinder. This lifting mechanism 20 is controlled by controlling the impact cushioning mechanism 24 using a lifting mechanism control unit 42 that is controlled by the control unit 40.

Moreover, the gate valve 4, which opens and closes between the load lock chamber 2 and the inspection chamber 3 is controlled by a valve control unit 44 that is controlled by the control unit 40.

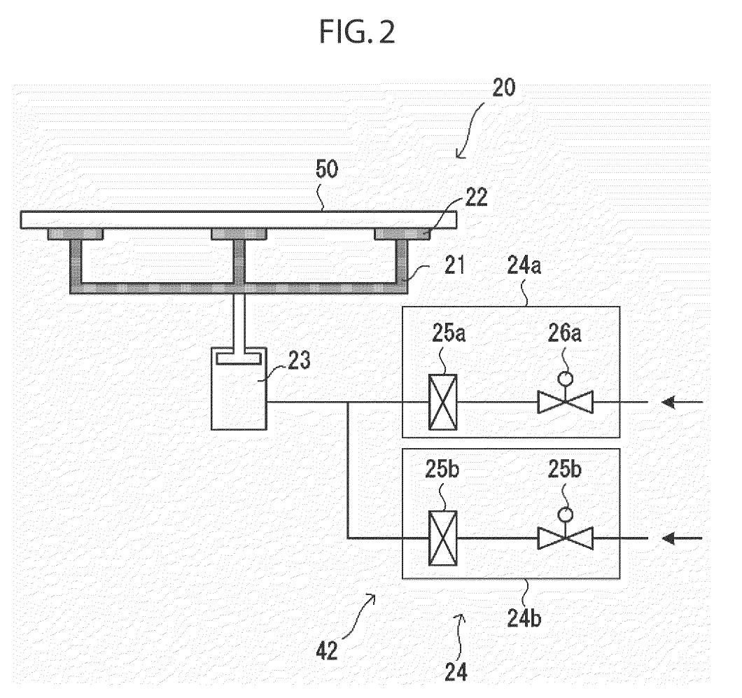

An example of a configuration of the lifting mechanism 20 will be explained using FIG. 2. Further, one of the multiple pallet support parts 22 provided in the lifting mechanism 20 is indicated in FIG. 2.

The lifting mechanism 20 is composed of multiple pallet support parts 22 that support a pallet and a mount 21 that maintains the aforementioned pallet support parts 22 for being driven up and down. The air cylinder 23 freely moves the mount 21 up and down.

This air cylinder drives by being supplied gas from a gas supply source (not indicated in the diagram) through the impact cushioning mechanism 24. The impact cushioning mechanism 24 is composed of a high-speed compressed air control circuit 24a, which configures a high-speed line, and a low-speed compressed air control circuit 24b, which configures a low-speed line; and the lifting velocities of the mount 21 and the pallet support parts 22 are controlled by switching between the high-speed line and the low-speed line.

The high-speed compressed air control circuit 24a is configured by a linear connection of a electromagnetic valve 25a and a flow rate adjuster 26a, while the low-speed compressed air control circuit 24b is configured by a linear connection of a electromagnetic valve 25b and a flow rate adjuster 26b.

One or the other of the high-speed line or the low-speed line is connected to the air cylinder 23 by exclusively switching between the electromagnetic valve 25a and the electromagnetic valve 25b. The flow rate regulator 26a and the flow rate regulator 26b regulate the flow rate of the gas supplied to the air cylinder 23. The flow rate regulator 26a of the high-speed compressed air control circuit 24a regulates the flow rate such that more gas is supplied than with the flow rate regulator 26b of the low-speed compressed air control circuit 24b. The air cylinder 23 drives at a speed corresponding to the flow rate set up by the flow rate regulator 26a or the flow rate regulator 26b.

Further, the configuration of the lifting mechanism 20 indicated in FIG. 2 indicates that the air cylinder 23 has mainly been driven upward by the compressed air supplied by the high-speed line or the low-speed line.

Meanwhile, the air cylinder 23 can be driven downward by reducing the pressure in the air cylinder 23, and the lowering velocity can be controlled by adjusting the flow rate by which gas inside the cylinder 23 is suctioned. The suctioning flow rate can be regulated by connecting a suction pump through the linear connection of the electromagnetic valve and the flow rate regulator in the same way as the impact cushioning mechanism 24. In this case as well, a high-speed line and a low-speed line with differing flow rates based on regulation by flow rate regulators are provided, and the downward drive velocity of the air cylinder 23 can be switched by exclusively selecting the high-speed line or the low-speed line.

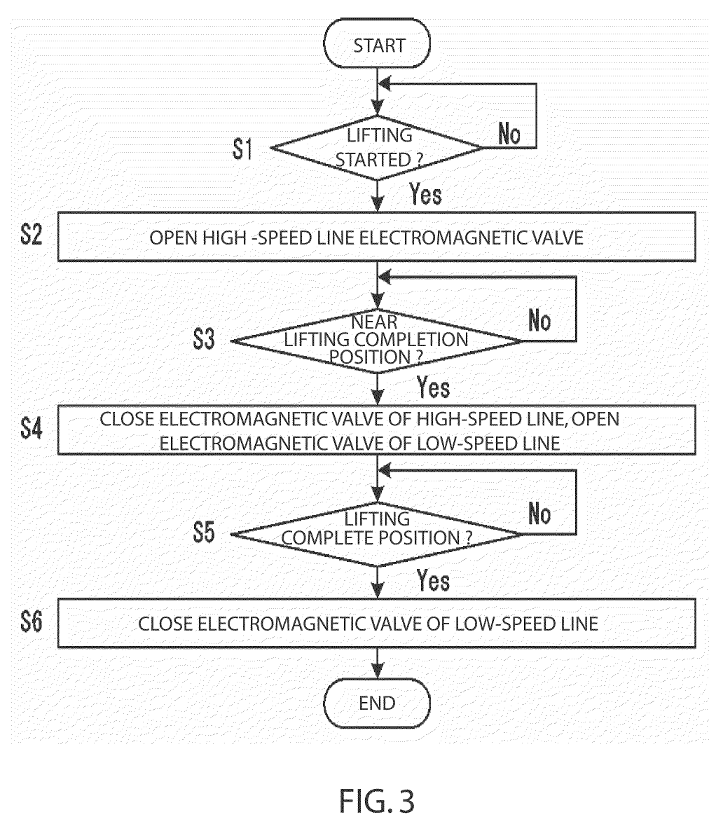

Next, the operation of the impact cushioning mechanism will be explained using FIG. 3 through FIG. 6.

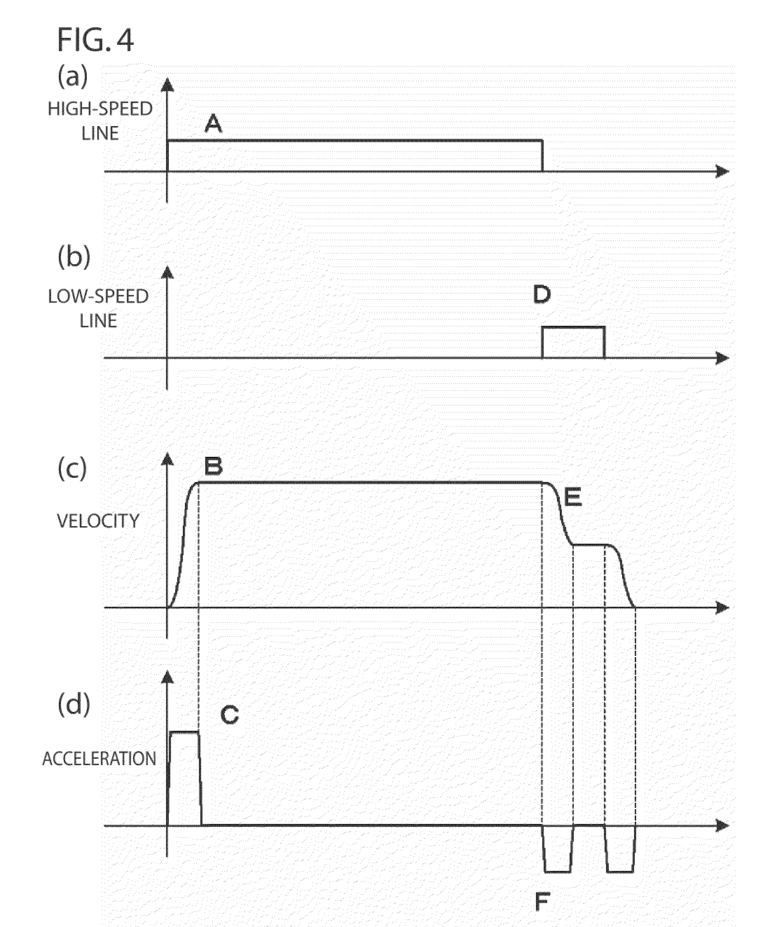

FIG. 3 is a flowchart of the low-speed switching operation when operation of the cylinder is being stopped, and FIG. 4 is an example of low-speed switching operations when operation of the cylinder is being stopped. This example is applicable to impact cushioning when raising a pallet. An example of the operation when raising a pallet will be described below.

When raising begins (S1), the air cylinder 23 is driven from the low position of the mount 21 by the high-speed line (A in FIG. 4(a)), and the mount 21 rises at high speed (B in FIG. 4(c)). Operation of the high-speed line is conducted by leaving the electromagnetic valve 25b of the low-speed compressed air control circuit 24b shut, and releasing the electromagnetic valve 25a of the high-speed compressed air control circuit 24a thereby supplying gas (for example, air) into the air cylinder 23 at a high flow rate (S2).

As this mount 21 begins to rise, the pallet accelerates rapidly (C in FIG. 4(d)), but no positional discrepancy between the pallet and the pallet support part is generated because this acceleration works in the direction of pushing the pallet onto the pallet support part.

Immediately before stopping the air cylinder 23 (S3), the air cylinder 23 is driven by switching from the high-speed line to the low-speed line (D in FIG. 4(b)), and the mount 21 is switched to low-speed (E in FIG. 4(c)). Operation of the low speed line is conducted by closing the electromagnetic valve 25a of the high-speed compressed air control circuit 24a, opening the electromagnetic valve 25b of the low-speed compressed air control circuit 24b, and lowering the flow rate of gas (for example, air) supplied to the air cylinder 23 (S4).

When stopping the mount 21, the velocity of the pallet support part is lower than that of the pallet mounted thereon, which attempts to maintain velocity through inertia, and therefore that lower velocity operates in a direction to create a positional discrepancy between the pallet and the pallet support part. By switching to this low-speed line, however, the force operating to make the pallet float up from the pallet support part becomes small compared to the force of gravity, and no positional discrepancy is generated between the pallet and the pallet support part.

When lifting reaches the end position (S5), the electromagnetic valve 25b of the low-speed line is closed, and the gas supply to the air cylinder 23 is stopped (S6).

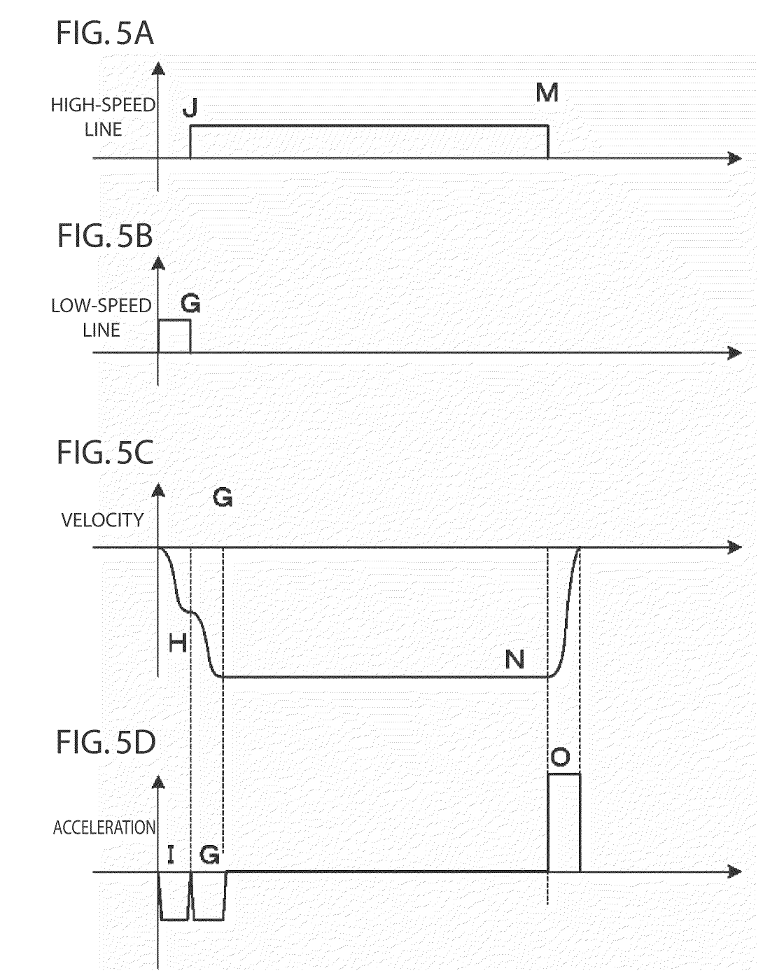

FIG. 5 is an example of the operation of switching to low speed when beginning operation of the cylinder, and can be applied to cushioning impact when lowering the pallet. An example of the operation to lower pallets will be explained below.

When lowering pallets, with the mount 21 in the upper position, the air cylinder 23 is driven by the low-speed line (G in FIG. 5(a)), and the mount 21 is lowered at low speed (H in FIG. 5(c)). Operation of the low-speed line is conducted by leaving the electromagnetic valve 25a of the high-speed compressed air control circuit 24a shut, and releasing the electromagnetic valve 25b of the low-speed compressed air control circuit 24b thereby limiting the flow rate of gas into the air cylinder 23.

When beginning to lower mount 21, the mount operates in a direction to create a positional discrepancy between the pallet and the pallet support part. However, the pallet accelerates slowly (I in FIG. 5(d)), and the force operating to cause the pallet to fly up from the pallet support part is small compared to the force of gravity, and therefore, no positional discrepancy is generated between the pallet and the pallet support part.

After the air cylinder 23 begins to descend, the air cylinder is driven by switching from the low-speed line to the high-speed line (J in FIG. 5(a)), and the mount 21 is switched to high speed (K in FIG. 5(c)). Operation of the high-speed line is conducted by closing the electromagnetic valve 25b of the low-speed compressed air control circuit 24b, opening the electromagnetic valve 25a of the high-speed compressed air control circuit 24a, and increasing the flow rate of gas (for example, air) supplied into the air cylinder 23.

When stopping the mount 21 (M in FIG. 5(a)), the velocity of the pallet support part is lowered in relation to that of the pallet mounted thereon, which attempts to maintain velocity through inertia (N in FIG. 5(c)). That acceleration operates in a direction to press the pallet onto the pallet support part (O in FIG. 5(d)), and therefore no positional discrepancy is generated between the pallet and the pallet support part.

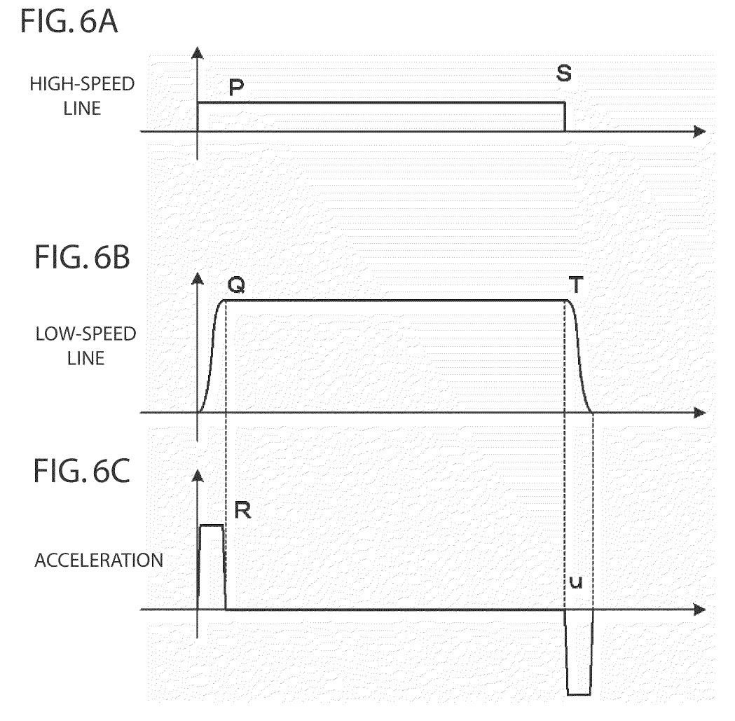

FIG. 6 is a diagram for explaining the drive of just the high-speed line without using the impact cushioning mechanism to switch between the high-speed line and the low-speed line.

With the mount 21 in the low position, the air cylinder 23 is driven by the high-speed line (P in FIG. 6(a)), and the mount 21 is driven at high speed (Q in FIG. 6(b)). When beginning to drive this mount 21, the pallet is accelerated rapidly (R in FIG. 6(c)). In addition, when stopping the air cylinder 23 (S in FIG. 6(a) and T in FIG. 6(b)), the pallet is also accelerated rapidly (U in FIG. 6(c)).

As described above, when driven only by the high-speed line, the pallet undergoes great acceleration when beginning drive and when stopping drive. If the direction of this acceleration is opposite to the direction of gravity, the substrate mounted on the pallet moves in a direction of separation from the pallet because of inertia, and a positional discrepancy may be generated between the pallet and the pallet support part.

In contrast, as indicated in FIG. 4 and FIG. 5, the acceleration to which the pallet is subjected is decreased by switching to the low-speed line, and even if the substrate mounted on the pallet moves in the direction of separation because of inertia, no positional discrepancy between the pallet and the pallet support part is generated.

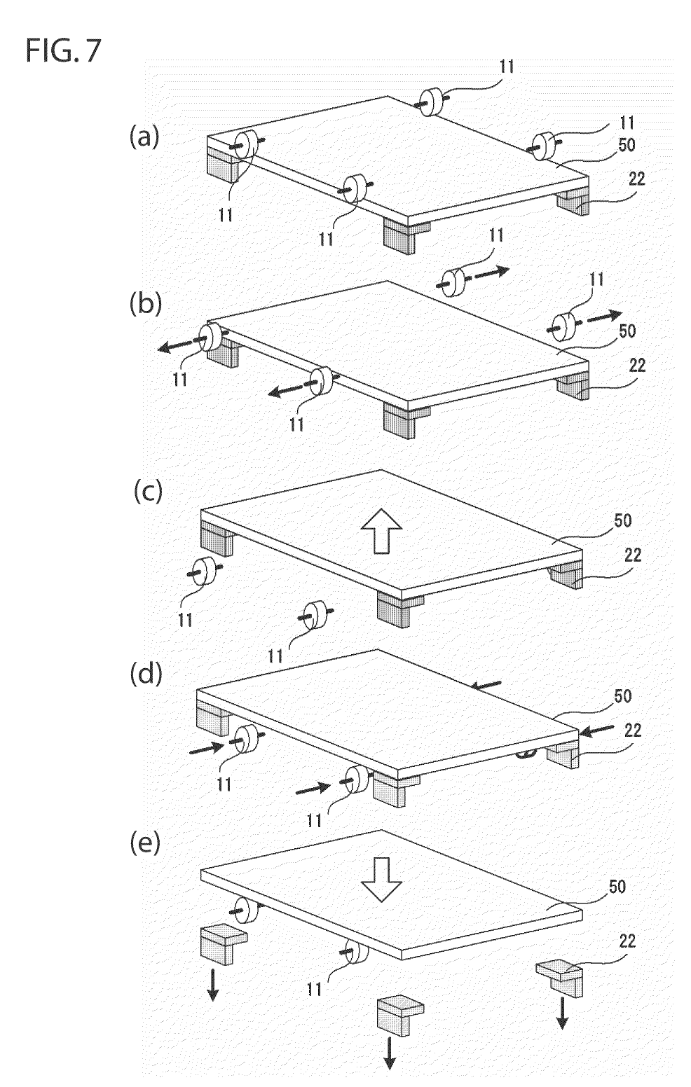

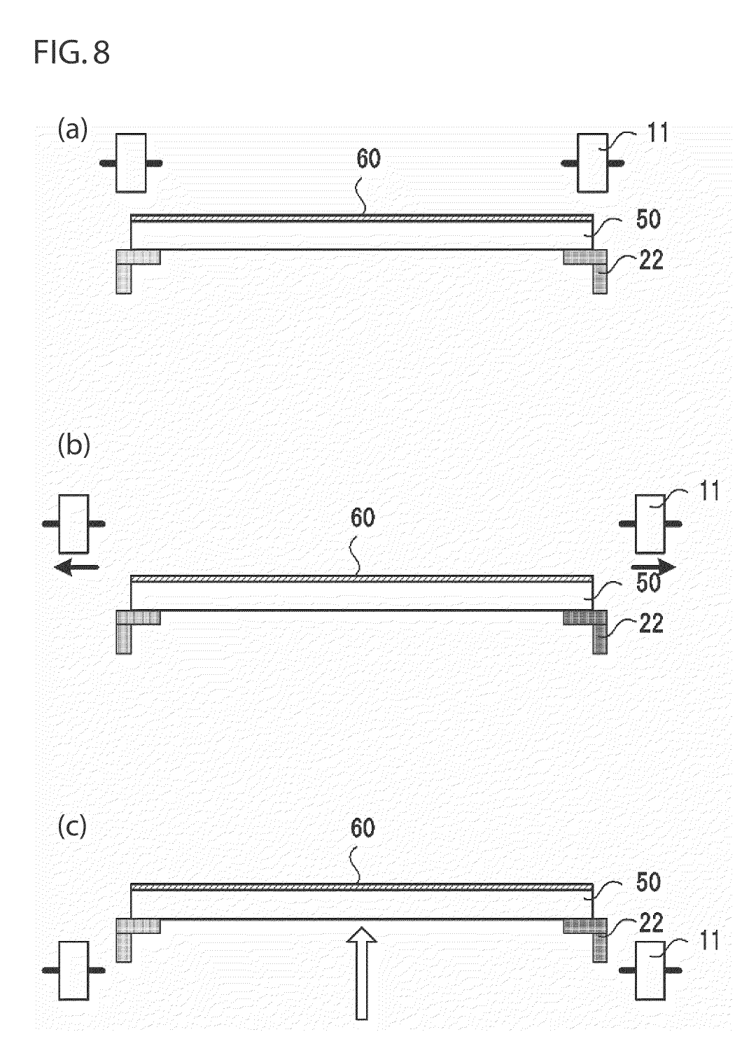

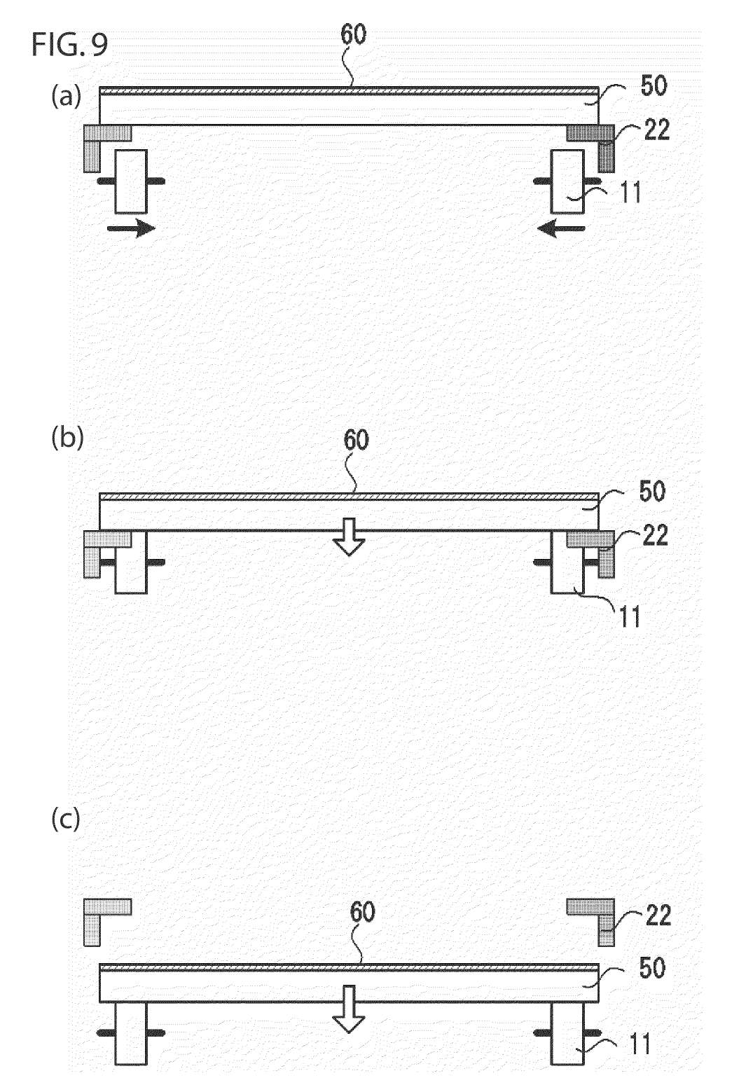

Next, in an operational example of the conveyance mechanism 10 and the lifting mechanism 20, the operation of placing a pallet on the conveyance rollers after having been lifted by the lifting mechanism 20 will be explained using FIG. 7 to FIG. 9. Further, FIG. 7 is a perspective drawing, and FIG. 8 and FIG. 9 are cross-sectional diagrams.

Initially, let the pallet support parts 22 be positioned below the conveyance rollers 11, and let a pallet 50 be supported on these pallet supports 22. At this time, the space between the conveyance rollers 11 on the two sides is the distance at which pallet 50 is placed (FIG. 7(a), FIG. 8(a)). Because the space between the conveyance rollers 11 on the two sides is the distance at which pallet 50 is placed, if the pallet 50, which is supported on the pallet support parts 22, is lifted by the lifting mechanism 20 in this state, the pallet 50 will bump into the conveyance rollers 11. Therefore, pallet 50 cannot be placed on the conveyance rollers 11.

Thus, the conveyance rollers 11 are moved to the outside, broadening the space between the rollers, such that the pallet support parts 22 and the pallet 50 can pass between the rollers (FIG. 7(b), FIG. 8(b)). After the distance between the rollers has been widened, the pallet support parts 22 are raised by the lifting mechanism 20 and pass between the rollers, and the pallet 50 is moved to a position above the conveyance rollers 11 (FIG. 7(c), FIG. 8(c)). After the pallet support parts 22 and the pallet 50 have been moved to a position above the conveyance rollers 11, the space between the roller is narrowed by moving the conveyance rollers 11 to the inside, setting up a space at which the pallet 50 can be placed on the conveyance rollers 11 (FIG. 7(d), FIG. 9(a)). Afterwards, the pallet support parts 22 are lowered, and the pallet 50 is placed on the conveyance rollers 11 (FIG. 7(e), FIG. 9(b)). After the pallet 50 is supported on the conveyance rollers 11, the pallet support parts 22 can be lowered further, and the pallet 50 can be conveyed by the conveyance rollers 11 (FIG. 9(c)).

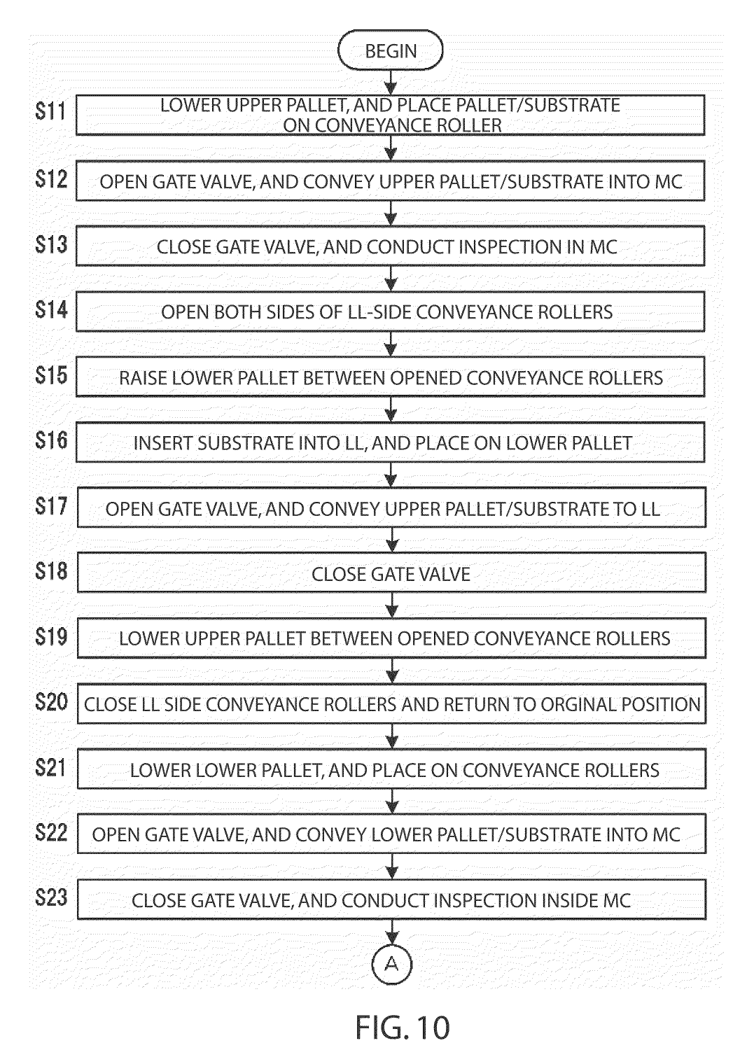

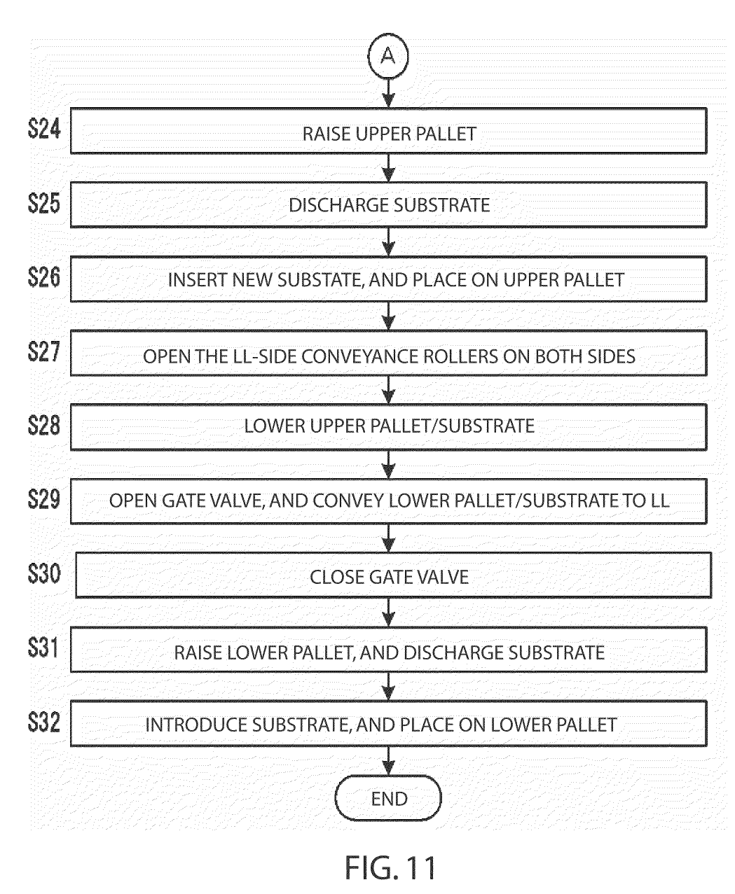

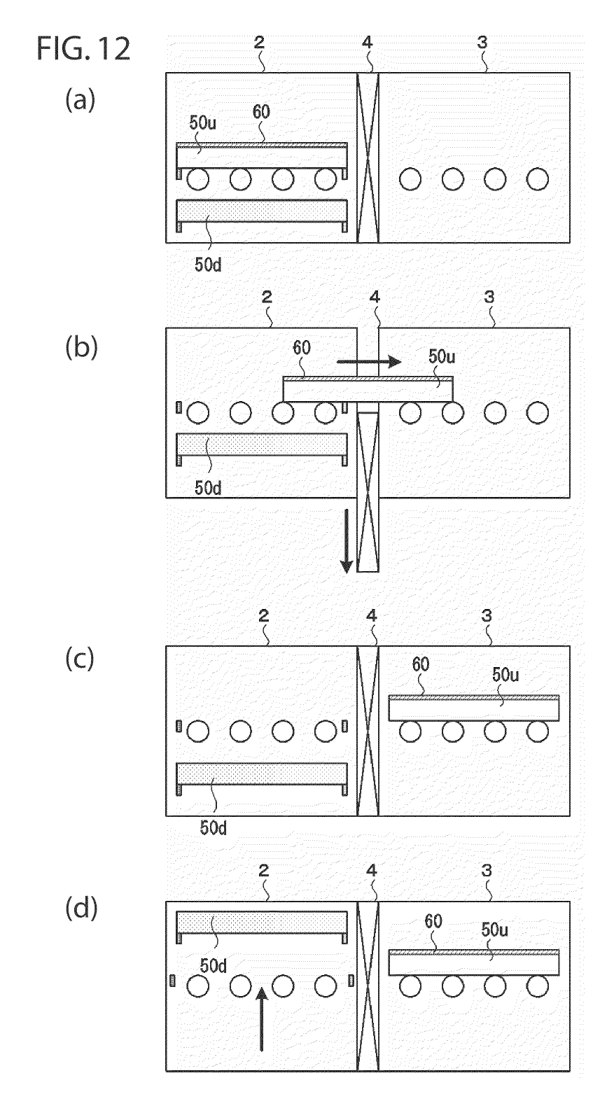

Next, an example of the operation of a pallet conveyance device of the present invention will be explained using the flowcharts in FIG. 10 and FIG. 11, and the operational explanatory diagrams in FIG. 12 to FIG. 20.

In one embodiment the conveyance device 10 in the load lock chamber 2 is provided with one set of conveyance rollers 11, two pallets are housed positioned above and below, and pallet switching is conducted to and from conveyance rollers 11. Moreover, as the initial state, assume that inside the 2 pallet support parts provided inside the load lock chamber two the upper pallet 50u is supported on the upper pallet support part, no pallet is supported on the lower pallet support part, nor is a pallet housed inside the inspection chamber 3. Further, assume that the upper pallet 50u is positioned above the conveyance rollers 11.

Initially, the upper pallet 50u is lowered by driving the lifting mechanism 20, and the substrate 60 to be supported is placed on the upper pallet 50u (S11) (FIG. 12(a)). Gate valve 4 is opened, the conveyance rollers 11 are driven, and the upper pallet 50u mounted on the conveyance rollers 11 is conveyed from the load lock chamber 2 into the inspection chamber 3. At that time, the lower pallet 50d is supported in a position below the conveyance rollers 11 (S12) (FIG. 12(b)).

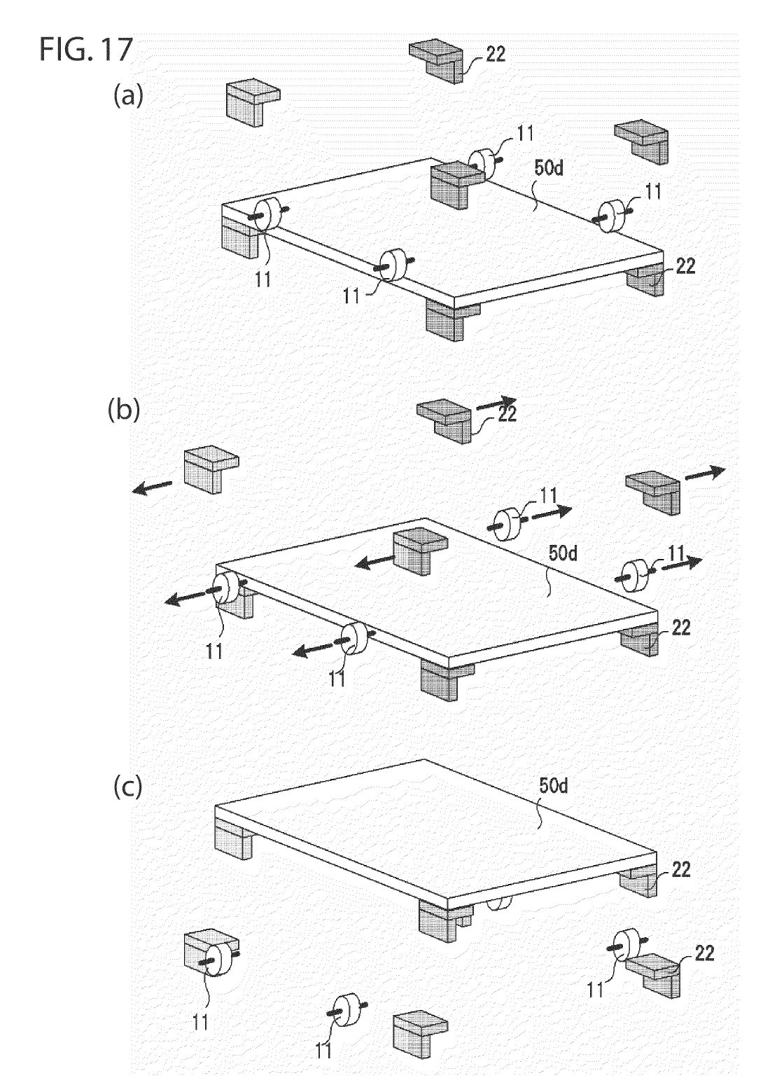

After the upper pallet 50u has been conveyed into the inspection chamber 3, the gate valve 4 is closed, and the substrate 60 mounted on the upper pallet 50u is inspected inside the inspection chamber 3 (S13) (FIG. 12(c), FIG. 17(a)).

While substrate inspection is being conducted in the inspection chamber 3, on the load lock chamber 2 side preparations are being conducted to convey the lower pallet 50d into the inspection chamber 3.

In the load lock chamber 2 the rollers of the conveyance rollers 11 are moved to the outside to widen the distance between rollers so that the lower pallet 50d can be moved upward between the rollers of the conveyance rollers 11 (S14) (FIG. 17(b)). The lower pallet 50d is raised and passed through the spread rollers of the conveyance rollers 11 (S15) (FIG. 12(d), FIG. 17(c)).

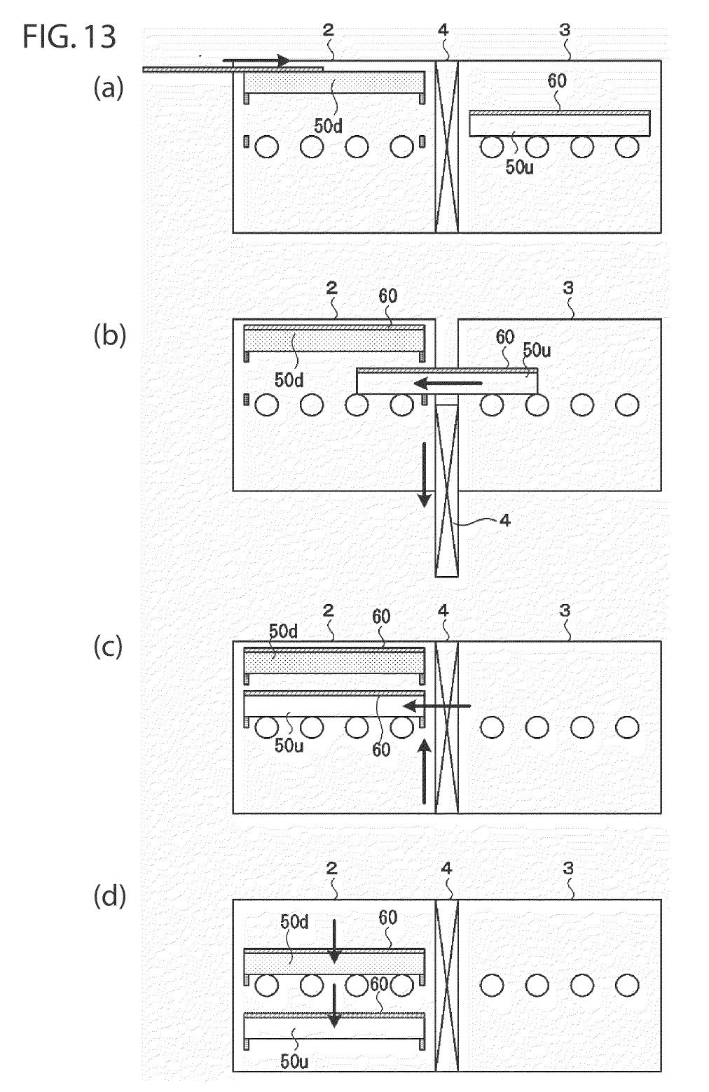

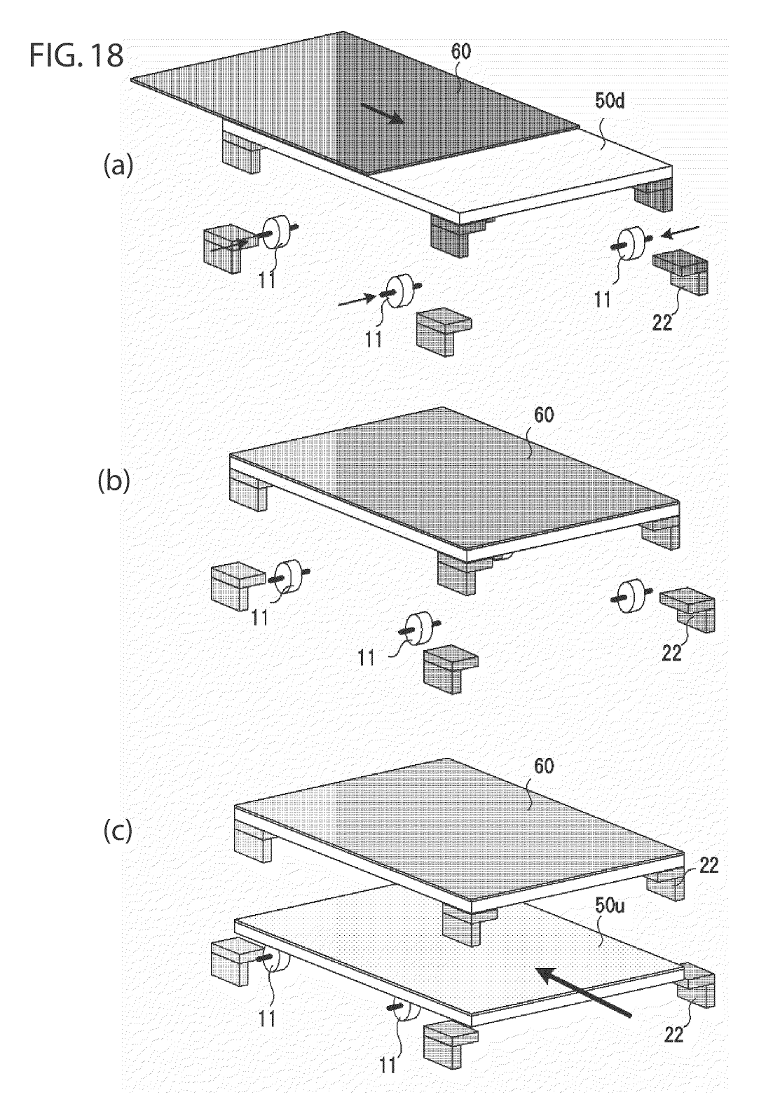

A substrate targeted for inspection is introduced from the outside, and is placed on the lower pallet 50d that has been raised above the conveyance rollers 11 (S16) (FIG. 13(a), FIGS. 18(a), (b)).

After substrate inspection has been completed in the inspection chamber 3, the gate valve 4 is opened, the upper pallet 50u is conveyed from the inspection chamber 3 to load lock chamber 2 through this gate valve 4 (S17) (FIG. 13(b), FIG. 18(c)). After the upper pallet 50u that has been conveyed out has been moved onto the conveyance rollers 11 in the load lock chamber 2, the gate valve 4 is closed (S18) (FIG. 13(c)).

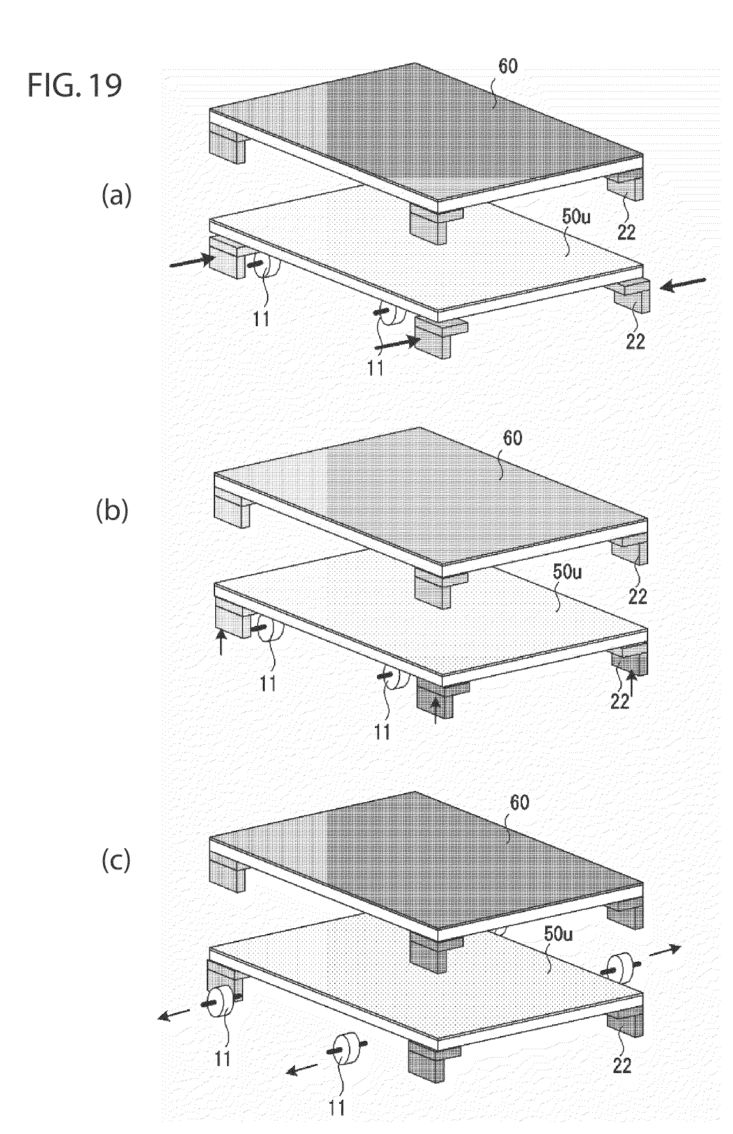

The upper pallet 50u is moved and switched onto the conveyance rollers 11. The moving and switching onto the conveyance rollers 11 can be conducted by supporting the upper pallet 50u using the pallet support part (FIGS. 19(a), (b)), and then moving the rollers outward (FIG. 19(c)).

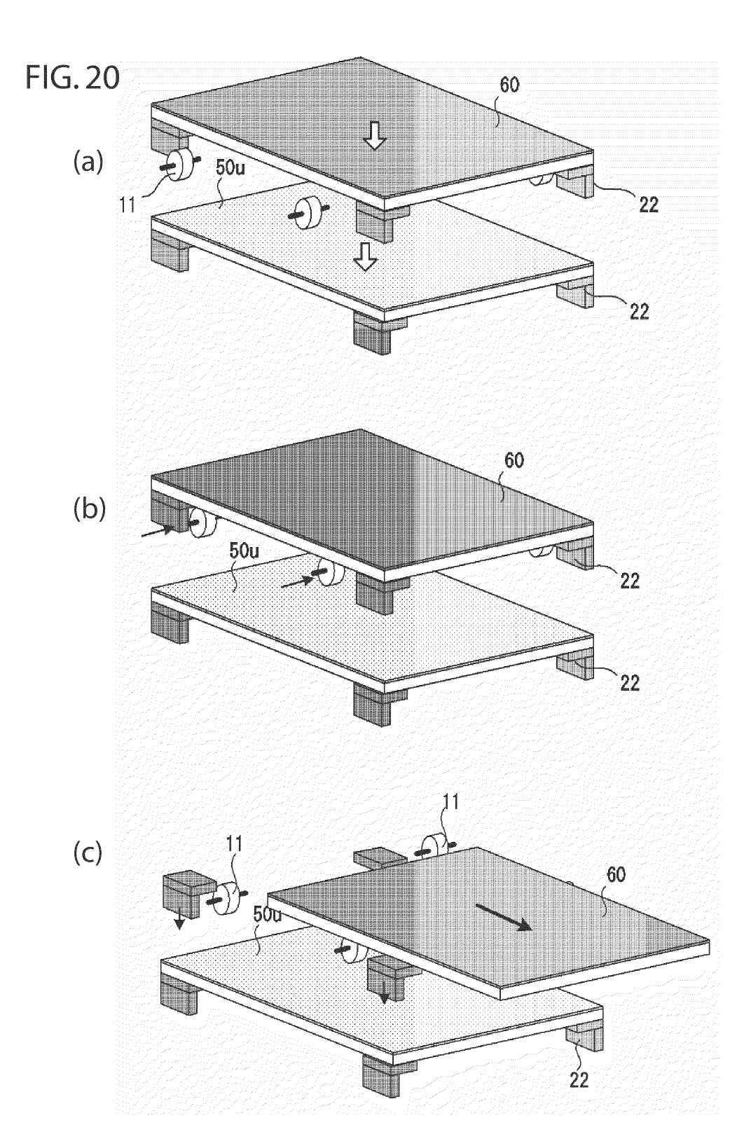

After the upper pallet 50u has been lowered through the opened rollers (S19) (FIG. 20(a)), the rollers of the conveyance rollers 11 are moved to the inside (S20) (FIG. 20(b)), the lower pallet 50d is lowered and placed on the conveyance rollers 11 (S21) (FIG. 13(d), FIG. 20(b)).

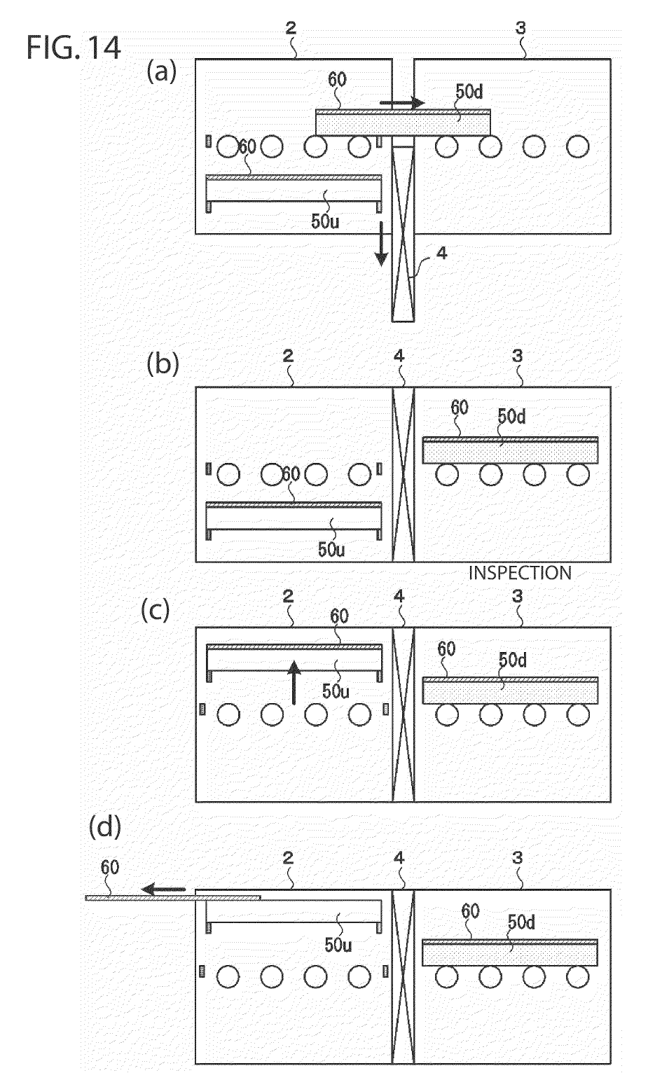

The gate valve 4 is opened, and the lower pallet 50d is conveyed into the inspection chamber 3 through this gate valve 4 (S22) (FIG. 14(a), FIG. 20(c)). After the lower pallet 50d has been conveyed into the inspection chamber 3, the substrate is inspected inside the inspection chamber 3 (S23) (FIG. 14(b)).

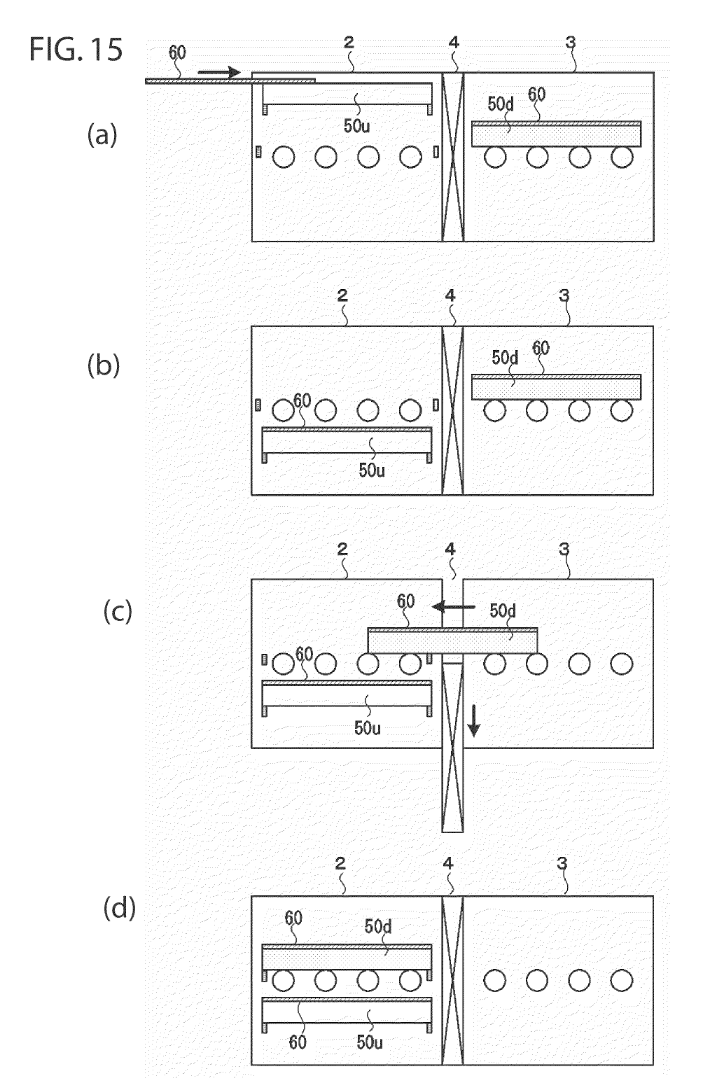

While the substrate mounted on the lower pallet 50d is being inspected in the inspection chamber 3, in the load lock chamber 2, the upper pallet 50u is raised (FIG. 14(c)), and the inspected substrate mounted on the upper pallet 50u is discharged (S25) (FIG. 14(d)). A substrate targeted for inspection is introduced and placed on the upper pallet 50u (S26) (FIG. 15(a)).

Moving the rollers of the conveyance rollers 11 on the load lock chamber 2 side to the outside to widen the distance between rollers makes it possible for the upper pallet 50u to move up and down through the rollers of the conveyance rollers 11 by (S27). The upper pallet 50u is then lowered and passed through the spread rollers of the conveyance rollers 11 (S28) (FIG. 15(b)).

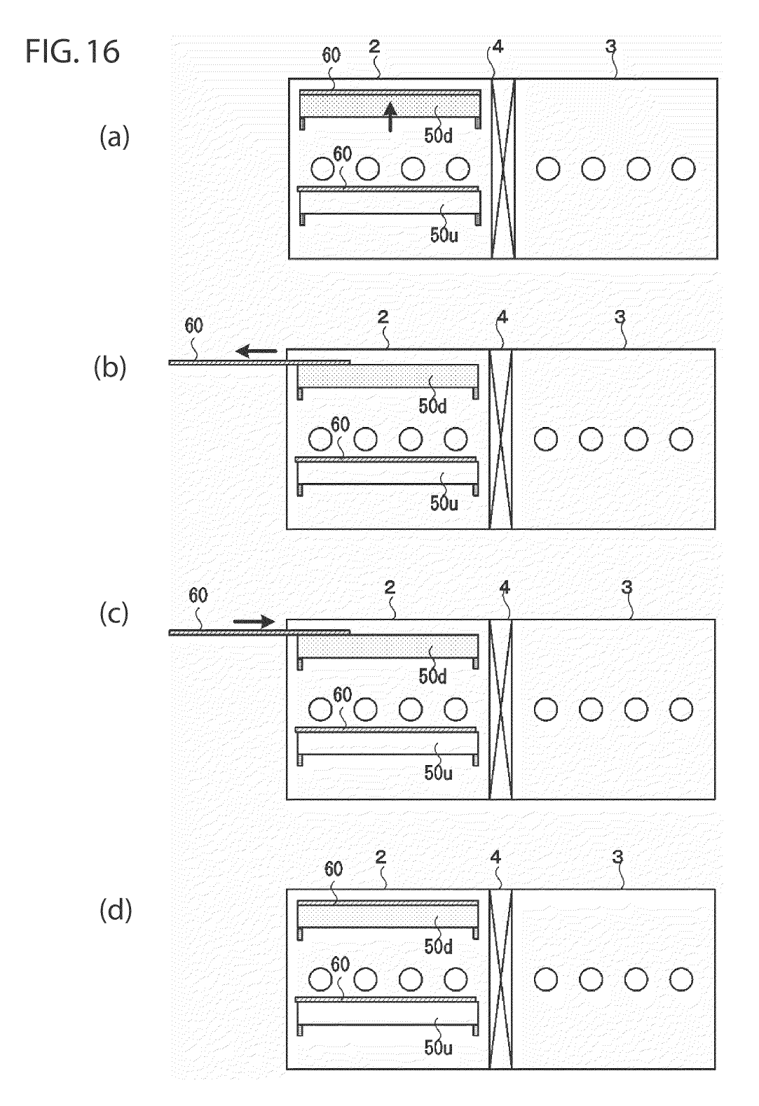

Gate valve 4 is opened, the lower pallet 50d in the inspection chamber 3 is conveyed out from the inspection chamber 3 into the load lock chamber 2 (S29) (FIG. 15(c)), and gate valve 4 is closed (S30) (FIG. 15(d)). The lower pallet 50d is raised by the lifting mechanism 20 on the load lock chamber 2 side (FIG. 16(a)), and the inspected substrate is discharged to the outside (FIG. 16(b)) (S31). A substrate targeted for inspection is introduced and placed on the lower pallet 50d (S32) (FIGS. 16(c)), (d)).

Further, in the example of the above configuration, an air cylinder mechanism was used as the lifting mechanism, but the present invention is not limited to an air cylinder mechanism. A mechanism driven by a motor ancillary to the conveyance device may also be used, and switching the pallet movement velocity between high-speed and low-speed may be controlled by regulating the drive current.

The pallet conveyance device of the present invention is not limited to conveyance of liquid crystal substrates, and can be applied to conveyance of semiconductor substrates.

The substrate inspection device of the present invention is not limited to inspection of liquid crystal substrates, and can be applied to inspection of semiconductor substrates.

1. A pallet conveyance device for moving a pallet that supports a substrate comprising:
a lifting mechanism moving the pallet up and down; and comprises:
an impact cushioning device cushioning an impact imparted to the substrate supported on the pallet during operation of the lifting mechanism, wherein the impact cushioning mechanism controls the operation of the lifting mechanism.

2. The pallet conveyance device according to claim 1, wherein
the impact cushioning mechanism switches a drive velocity of said lifting mechanism;
wherein the drive velocity is switched to low speed either when beginning operation of said lifting mechanism or slightly before completing operation; and
wherein the drive velocity is switched to high-speed in drive periods other than said low-speed periods.

3. The pallet conveyance device according to claim 2, wherein
during a raising operation of the lifting mechanism, the lifting operation is begun at the high-speed drive velocity, and the drive velocity at a specified period prior to completing the raising operation is switched to low-speed; and
during a lowering operation of the lifting mechanism, the lowering operation is begun at the low-speed drive velocity, and after a specified period has passed after lowering has begun the drive velocity is switched to high-speed.

4. The pallet conveyance device according to claim 2, wherein the
lifting mechanism is an air cylinder mechanism that drives using pneumatic pressure;
wherein the impact cushioning mechanism has two compressed air line systems comprising a high-speed compressed air line and a low-speed compressed air line for supplying gas at differing flow rates to the air cylinder mechanism;
wherein a specified period, the air cylinder mechanism is driven at low speed by using the low-speed compressed air line to reduce the supply volume of gas per unit time supplied to said air cylinder mechanism; and
wherein the drive period other than the specified period, the air cylinder mechanism is driven at high speed by using the high-speed compressed air line to increase the supply volume of gas per unit time supplied to said air cylinder mechanism.

5. The pallet conveyance device according to claim 1 further comprising:
a conveyance mechanism that moves one pallet of a plurality of pallets horizontally, and
wherein the lifting mechanism can move and switch the pallet to and from the conveyance mechanism, and the pallet is moved and switched by moving up and down and to and from said conveyance mechanism.

6. The pallot conveyance device according to claim 5, further comprising,
an inspection chamber for inspecting substrates, and
a load lock chamber for conveying substrates to and from the inspection chamber;
wherein the conveyance mechanism comprises a first set of conveyance rollers provided in the inspection chamber for inspecting substrates, and a second set of conveyance rollers provided in the load lock chamber for conveying substrates in and out of the inspection chamber, and
the plurality of pallets that the lifting mechanism supports in the load lock chamber are conveyed to and from the first set of conveyance rollers by sharing said second set of conveyance rollers.
